(19) United States
(12) Patent Application Publication
(10) Pub. No.: US 2008/0302295 A1
(43) Pub. Date: Dec. 11, 2008

(54) Method of Evaluating Quality of Silicon Single Crystal

(76) Inventors: Toshirou Kotooka, Kanagawa (JP); Shin Matsukuma, Kanagawa (JP); Toshiaki Saishoji, Kanagawa (JP)

Correspondence Address: Husch Blackwell Sanders, LLP;Welsh & Katz, 120 S RIVERSIDE PLAZA, 22ND FLOOR, CHICAGO, IL, 60606, US

(21) Appl. No.: 11/659,061

(22) PCT Filed: Aug. 1, 2005
(86) PCT No.: PCT/JP05/14049

§ 371 Date: Jan. 31, 2007

(30) Foreign Application Priority Data
Aug. 4, 2004 (JP) 2004-229408

(51) Int. Cl. C30B 15/20

(52) U.S. Cl. 117/14

(57) ABSTRACT

In the crystal growth rate (V), there is such a permissible range that the given quality of silicon single crystal can be maintained. This permissible range is determined in advance. The log data of crystal growth rate (V) is measured in the pulling up of silicon single crystal, and using the log data, the actual value of crystal growth rate (V) is determined. The actual value is compared with the permissible range. Any region of silicon single crystal corresponding to crystal growth rate (V) falling within the permissible range is judged as being a conforming region satisfying given standards, while any region of silicon single crystal corresponding to crystal growth rate (V) falling outside the permissible range is judged as being a defective region not satisfying given standards.

### TECHNICAL FIELD

The present invention relates to a method of evaluating quality of silicon single crystal in which the quality of a silicon single crystal pulled up from a silicon melt is evaluated, log data of control parameters during crystal growth being employed to evaluate quality across all regions of the crystal.

### BACKGROUND ART

A demand for higher integration degree and miniaturization of semiconductor devices have arisen in recent years, and this demand has been accompanied by increasingly severe demands in terms of silicon wafer quality. A major characteristic of silicon wafer quality pertains to grown-in defects that appear during growth of the silicon single crystal. Grown-in defects have an undesirable effect during semiconductor device processing on, for example, the dielectric strength and leakage current characteristics of the insulating oxide film, and are a cause of reduced yield. Accordingly, the density of the defects must be reduced or completely removed. Grown-in defects may broadly divided into vacancy-type defects (voids) and silicon interstitial-type defects (dislocation clusters) and, depending on the respective methods for the detection thereof, the former is referred to as either LPD (Laser Point Defect), COP (Crystal Originated Particle), FPD (Flow Pattern Defect) or LSTD (Laser Scattering Tomography Defect) amongst others, while the latter is referred to as L/D (Large Defect), LEPD (Large Etch Pit Defect) and LSEPD (Large Secco Etch Pit Defect) amongst others. Hereinafter, if the evaluation method is not specified, the vacancy-type defect refers to a VD (Vacancy type Defect) and the silicon interstitial-type defect refers to an ID (self-Interstitial type Defect). The distribution of these defects and their behaviour of generation are known to be determined by the crystal pulling velocity, that is to say, the crystal growth velocity (hereinafter, the crystal growth velocity V), and the temperature gradient in the neighborhood of the melting point of the silicon single crystal in the pulling axis direction (hereinafter, the temperature gradient G). In addition, it has been revealed that, as the crystal growth velocity V is being reduced, the defect distribution within the silicon single crystal changes from a VD generating range to an ID generating range, and a non-defect range exists in a range between these ranges. Accordingly, it is clear that a more accurate control of the crystal growth velocity V and the temperature gradient G must be performed in order to improve the quality of a silicon wafer.

However, this control accuracy requires a level of control capability close to or higher than that possessed by conventional manufacturing devices or control systems. Therefore, it is clear that along with a need for a more strict control, there is a need for improved quality inspection accuracy of the silicon single crystal corresponding to the more strict control.

More specifically, a single crystal diameter control mechanism in silicon single crystal growth normally involves detection of the crystal diameter (or crystal weight corresponding thereto) as required, and feedback control for the temperature of the silicon melt and the crystal growth velocity V with respect to the difference from a target crystal diameter. Accordingly, while a control has been performed with a fluctuation level of the order of ±0.02 mm/min with respect to a set silicon growth velocity, a need has arisen that the permissible fluctuation width of the silicon growth velocity V should be the equivalent or lesser order from the viewpoint of satisfying the demanded quality of the product. At the hitherto employed control levels, however, a partial failure to meet the quality standards occurs and the need for a more accurate inspection and judgment thereof arises.

The steps involved in the manufacture of a silicon wafer that serves as a substrate of a semiconductor device may be broadly divided into a single crystal growth step and a wafer-processing step. Following each step, the inspection for the product is carried out. The process flow of the typical wafer manufacturing steps will now be explained with reference to FIG. 12.

A silicon single crystal grows in the silicon crystal growth step. More specifically, the silicon single crystal is pulled up from a silicon melt, thereby forming an ingot-shaped silicon single crystal (Step 1201). The silicon single crystal is divided into blocks of a predetermined length, all of which are then sliced (Step 1202). A quality inspection is carried out on the divided blocks (interim inspection) (Step 1203). This interim inspection involves a so-called sampling inspection in which an inspection test piece is extracted from both ends of the divided block, and inspections on such items as oxygen concentration, resistance, stacking fault and grown-in defects are carried out on the test piece. To detect the grown-in defects, a selected etching method such as seco etching is employed in which VD and ID are detected. When a wafer meets the prescribed standards, the block from which the wafer was extracted is judged to have passed, and is forwarded to the subsequent wafer-processing step.

The wafer-processing step involves a chemical-mechanical polishing processing of the wafer (mirror surface finishing processing) (Step 1204). The wafer on which this wafer processing has been completed is then subjected to a product inspection (final detection) (Step 1205).

The detection of the grown-in defects carried out in this product inspection involves irradiation of a laser light onto the wafer surface in which a particle counter is employed to detect scattered light generated by dust (particles) or the defects present on the wafer surface at this time. The defects detected here are the VD defects referred to as LPD described above. The particle counter is able to carry out a non-destructive inspection, whereby all of the VDs can be fully inspected. On the other hand, although it is possible to detect the ID by a non-destructive evaluation method, such a method has a problem for the practical application in the regular inspection because of the extremely low ID density of the order of 10³ to 10⁴/cm³. Therefore, a method in which the product assurance is based substantially on the judgment of a sampling inspection carried out as an interim inspection has been employed. This suggests that improved inspection accuracy has been required.

Wafers for which all inspection items including the inspection of grown-in defects are judged as having passed in the product inspection are consigned as products (OK judgment of Step 1205, Step 1206), and wafers judged as having failed the inspection are discarded as defective products (NG judgment of Step 1205, Step 1207).

### DISCLOSURE OF THE INVENTION

### Problems to be Solved by the Invention

Current quality inspection involves merely conjecture of the quality of a block based on the quality of a sample extracted from the block, and by no means can be described as a high accuracy method of inspection.

For example, if the test piece wafer is judged to be of high quality, the block from which the test piece wafer is extracted is judged to be of high quality, and a mirror surface polishing is performed on all wafers sliced from this block. However, sometimes wafers of low quality are contained within these wafers. Because they will be judged as failing at the product inspection stage, they will be eventually discarded. A problem from the viewpoint of operational efficiency arises due to the implementation of such ineffectual operation.

Conversely, when the test piece wafer is judged to be of low quality, the block from which the test piece wafer is extracted is judged to be of low quality and all wafers sliced from this block are discarded. However, sometimes wafers of high quality are contained within these wafers. A problem from the viewpoint of yield arises due to the discarding of wafers that meet the predetermined standards.

Although dependent on the wafer quality demanded in future, it is highly probable that the problems described above will be marked in the conventional sampling inspection, and such sampling inspection is regarded as an inadequately functioning quality inspection.

With the foregoing situations in mind, it is an object of the present invention to achieve a resolution to these problems and improve operational efficiency and yield by improving the accuracy of the wafer quality inspection.

### Means to Solve the Problems

First invention discloses a method of evaluating quality of a silicon single crystal in which the quality of the silicon single crystal pulled up from a silicon melt is evaluated, comprising measuring a control parameter that has an effect on the quality of the silicon single crystal during pulling up of the silicon single crystal; and determining a quality satisfactory part and a quality unsatisfactory part of the silicon single crystal by employing a predetermined permissible range of a control parameter and the measured control parameter.

Second invention discloses a method of evaluating quality of a silicon single crystal in which the quality of the silicon single crystal pulled up from a silicon melt is evaluated, comprising a process for measuring a control parameter having an effect on the quality of the silicon single crystal during pulling up of the silicon single crystal; a process for determining a correlative relationship between a silicon single crystal part and the control parameter by employing the measured control parameter; and a process for comparing a permissible range of a control parameter set in advance and the control parameter in the correlative relationship to judge the silicon single crystal part corresponding to the control parameter in the permissible range as a quality satisfactory part, and the silicon single crystal part corresponding to the control parameter outside the permissible range as a quality unsatisfactory product part.

A third invention is characterized in that in the first or second inventions, the control parameter is the crystal growth velocity of the silicon single crystal.

A fourth invention is characterized in that in the first or second inventions, the control parameter is a distance from a lower edge of a heat-shielding plate arranged above a silicon melt for shielding the silicon single crystal from radiant heat to a surface of the silicon melt.

When the silicon single crystal is pulled up, the control parameters that exert an effect on the quality of the silicon single crystal which include, for example, the silicon single crystal pulling velocity, that is to say, a crystal growth velocity V, and the distance to the silicon melt surface from the lower end of a heat-shielding plate disposed above the silicon melt and arranged for shielding the silicon single crystal from radiant heat, that is to say, a GAP distance d, are controlled. These control parameters have a range within which the silicon single crystal is maintained at a predetermined quality. This range is referred to as the permissible range.

As shown in FIG. 3, the crystal growth velocity V has a permissible range which corresponds to each part of the silicon single crystal. This permissible range is determined in advance. Log data of this control parameter is measured when the silicon single crystal is pulled up, and this log data is employed to determine the actual value of the crystal growth velocity V. The actual value is compared to the permissible range.

In FIG. 3, the crystal growth velocity V corresponding to a section from a position L0 to a position L1 and a section from a position L2 to a position L3 of a silicon single crystal 22 constitute the permissible range. The crystal growth velocity V corresponding to the section from position L1 to position L2 of the silicon single crystal 22 is outside the permissible range. In this case, the section from the position L0 to the position L1 and the section from the position L2 to the position L3 of a silicon single crystal 22 are judged as a satisfactory product that satisfies the predetermined standards, and the section from the position L1 to the position L2 is judged as a defective product that does not satisfy the predetermined standards.

### EFFECT OF THE INVENTION

According to the present invention, log data of the control parameters during crystal growth is employed to evaluate the quality of all parts of the silicon single crystal. Because all parts of the silicon single crystal are evaluated, the accuracy of the quality inspection can be said to be comparatively higher than the conventional sampling inspection in which only a part of the silicon single crystal is extracted and evaluated. In addition, the satisfactory product part and unsatisfactory product part can be reliably distinguished. Accordingly, the implementation of wafer finishing processing on unsatisfactory wafers is avoided and the operational efficiency is improved. In addition, the discarding of satisfactory wafers is avoided and yield is improved.

### BEST MODE FOR CARRYING OUT THE INVENTION

An embodiment of the present invention will be hereinafter explained with reference to the drawings.

FIG. 1 is a diagram that shows the configuration of a CZ method silicon single crystal pulling apparatus used in this embodiment. A silicon single crystal pulling apparatus 10 comprises, in the interior of a furnace 11, a crucible 12 for housing a silicon melt 21 that is freely elevatable in the vertical direction and freely rotatable around its elevation axis, a side surface heater 13 provided surrounding the crucible side surface for principally heating the crucible side surface, a base surface heater 14 provided opposing the crucible side surface for principally heating the crucible base surface, and a heat-shielding member 15 provided above the crucible for shielding a silicon single crystal 22 from radiant heat.

The control parameters applied in this embodiment are “crystal growth velocity V” and a “distance d from a heat-shielding member lower end 15a to a silicon melt liquid surface 21a”. The crystal growth velocity V is determined from the operation of a single crystal pulling unit not shown in the drawings. On the other hand, for the purpose of determining the distance d from the heat-shielding member lower end 15a to the silicon melt liquid surface 21a, the silicon single crystal pulling apparatus 10 comprises a distance measurement apparatus 31 provided on the exterior of the furnace 11 which comprises a laser light irradiator and receiver, a scan mirror 32 provided at the exterior of the furnace 11 that is freely movable and rotatable, and a prism 33 provided in the interior of the furnace 11 that opposes the scan mirror 32 by way of an incident window 11a. The gap between the heat-shielding member lower end 15a and the silicon melt liquid surface 21a is referred to in this description as a “GAP”.

The method for measurement of the GAP distance d performed in this embodiment will now be explained.

The laser light emitted from the laser light irradiator of the distance measurement apparatus 31 is reflected by the scan mirror 32, transmitted through the incident window 11a, refracted by the prism 33, and irradiated onto the silicon melt liquid surface 21a. Furthermore, the laser light is reflected by the silicon melt liquid surface 21a and irradiated onto the lower surface of the heat-shielding member lower end 15a from where it is subsequently scattered. Part of the scattered light is reflected by the silicon melt liquid surface 21a, refracted by the prism 33, transmitted through the incident window 11a, and reflected by the scan mirror 32 to fall incident on the receiver of the distance measurement apparatus 31. The distance measurement apparatus 31 employs the distance between the laser light irradiator and receiver and the irradiated angle of the laser light and received angle of the scattered light to calculate an optical path distance Dw from the laser light irradiator to the receiver.

The scan mirror 32 is rotated or moved so that the irradiated position of the laser light is moved from the silicon melt liquid surface 21a to the upper surface of the heat-shielding member lower end part 15a. Thereupon, the laser light emitted from the laser light irradiator of the distance measurement apparatus 31 is reflected by the scan mirror 32, transmitted through the incident window 11a, refracted by the prism 33, and irradiated onto the upper surface of the heat-shielding member lower end part 15a from where it is scattered. Part of the scattered light is refracted by the prism 33, transmitted though the incident window 11a, and reflected by the scan mirror 32 to fall incident on the receiver of the distance measurement apparatus 31. The distance measurement apparatus 31 employs the distance between the laser light irradiator and receiver, the irradiated angle of the laser light and the received angle of the scattered light to calculate an optical path distance Ds from the laser light irradiator to the receiver.

The difference between the optical path distances Dw and Ds is equivalent to (distance from the upper surface of the heat-shielding member lower end 15a to the silicon melt liquid surface 21a)×2. The GAP distance d is determined from the difference between the optical path distances Dw and Ds with the thickness of the heat-shielding member lower end 15a being taken into consideration. In this embodiment, however, the thickness of the heat-shielding member lower end 15a is ignored. Accordingly, the GAP distance d is calculated as:

GAP distance d=(Dw−Ds)/2 (1)

Next, the steps for manufacturing a silicon wafer to which this present invention is applied will be explained. The explanation is of a case in which the crystal growth velocity V and the GAP distance d are employed as the control parameters. FIG. 2 is a flow chart showing the steps for manufacturing a silicon wafer including the present invention.

A silicon single crystal is pulled up from the silicon melt to form an ingot (Step 201). The crystal growth velocity V and GAP distance d are measured regularly and at a predetermined time during the pulling up of the silicon single crystal, and the measured results thereof are stored as log data in a memory not shown in the drawing. An average processing is performed on the crystal growth velocity data of this log data while the GAP distance data thereof is data processed (Step 202).

The average processing of the crystal growth velocity will be explained. The silicon single crystal part as explained in this description refers to a position on the silicon single crystal where the longitudinal direction of the silicon single crystal has been taken as the direction of displacement. The defect distribution of the wafer sliced from an arbitrary part of the silicon single crystal has a very strong correlative relationship with the average value of the crystal growth velocity V implemented when the section of the arbitrary part and front and rear predetermined sections thereof (for example, front 30 mm, back 40 mm) are formed. Accordingly, in this embodiment, the crystal growth velocity V implemented when a section of a certain part of a silicon single crystal and front and rear predetermined sections thereof are formed is extracted from the log data, the average value of the extracted crystal growth velocity data is calculated, and this calculated value is deemed to be the crystal growth velocity V corresponding to the arbitrary part noted above. In this embodiment, the correlative relationship between every parts of the silicon single crystal and the crystal growth velocity V is determined by taking the crystal growth velocity V determined in this way as the actual value.

The data processing of the GAP distance data will be explained. This processing involves a sampling of the GAP distance data from the log data at predetermined intervals. This processing affords improved processing efficiency without undesirably affecting the quality inspection judgment results.

A permissible range is set respectively for each of the crystal growth velocity V and the GAP distance d, and a judgment of whether or not the crystal growth velocity V and GAP distance d are within the permissible ranges following the average processing is made (Step 203). The permissible range constitutes a range of the control parameter established for each of the sections of the silicon single crystal within which, when an arbitrary section of silicon single crystal is being grown, the quality of this section can be maintained at a predetermined standard. The permissible ranges for the crystal growth velocity V and GAP distance d and the method for determining the ranges will be described later.

The judgment performed in Step 203 will be specifically explained with reference to FIG. 3. FIG. 3 is a diagram that shows one example of the correlative relationship between the actual value of the crystal growth velocity, the permissible range of the crystal growth velocity, and the silicon single crystal part. In FIG. 3 the crystal growth velocity V corresponding to the section from the position L0 to the position L1 and the section from the position L2 to the position L3 of the silicon single crystal 22 lies within the permissible range. The crystal growth velocity V corresponding to the section from the position L1 to the position L2 of the silicon single crystal 22 is outside the permissible range. In this case, the section from the position L0 to the position L1 and the section from the position L2 to the position L3 of the silicon single crystal 22 constitute the permissible range and are judged as a satisfactory product that satisfies the predetermined standards, while the section from the position L1 to the position L2 is judged as an unsatisfactory product that does not satisfy the predetermined standards.

A permissible range of GAP distance d is also similarly set, and the section within which the GAP distance d of the silicon single crystal lies in the permissible range is judged as a satisfactory product that satisfies the predetermined standards, while the section of the GAP distance d outside the permissible range is judged as an unsatisfactory product that does not satisfy the predetermined standards.

The explanation will be continued with reference again to FIG. 2. If all regions of the silicon single crystal constitute a satisfactory product, the silicon single crystal is divided into blocks of a predetermined length that are then sliced into the whole number (OK decision of Step 203, Step 205). On the other hand, if some regions of the silicon single crystal constitute an unsatisfactory product, the cutting position is altered so that both ends of the region judged as unsatisfactory are cut, after which the silicon single crystal is divided into blocks of a predetermined length with only the satisfactory product blocks being sliced into the whole number (NG decision of Step 203, Step 204, Step 205). Blocks containing the unsatisfactory product are discarded (Step 206).

While all wafers should at this stage constitute satisfactory products, the conventional inspection (interim inspection) may be implemented together with other elements for inspection (Step 207). However, in this embodiment, the quality inspection pertaining to grown-in defects may be omitted. All sliced wafers are moved to the next step for wafer finish processing.

The processing that follows wafer finish processing (Step 208 and thereafter) is identical to the conventional processing described by FIG. 10.

The wafer finish processing involves a wafer chemical-mechanical polishing finish processing (mirror finish processing) (Step 208). A product inspection (final inspection) is carried out on wafers on which the wafer finish processing has been completed (Step 209). The wafers judged as having satisfactorily met the predetermined standards of the product inspection are consigned as products (OK decision in Step 209, Step 210), and the wafers judged as having failed to satisfy these standards are discarded as unsatisfactory products (NG decision of Step 209, Step 211).

Next, the permissible ranges of the crystal growth velocity V and GAP distance d and method for the determining thereof will be explained.

First, the permissible range will be explained.

FIG. 4 is a diagram that shows the relationship between the crystal growth velocity V and LPD number in an arbitrary part of the silicon single crystal. While only a part of the data is indicated in FIG. 4, the results of actual testing confirmed the data as being distributed in the range enclosed by an ellipse E. As shown in FIG. 4, a correlative relationship exists between the crystal growth velocity V and the LPD number. If the crystal growth velocity V increases the LPD increases and, conversely, if the crystal growth velocity V decreases the LPD decreases. This relationship suggests that when the crystal growth velocity V decreases the LPD decreases. However, ID are generated in the outer circumferential part of the wafer when the crystal growth velocity V drops below a predetermined velocity.

While several wafer product standards exist, there are the product standards, “LPD of a predetermined number or less” and “no ID”. The correlative relationship shown in FIG. 4 can be employed to specify the range of the crystal growth velocity V corresponding to these product standards. For example, the upper limit value (VUL) of the crystal growth velocity V that sets LPD to a predetermined number or less can be specified, and the lower limit value (VLL) of the crystal growth velocity V at which the ID is eliminated can be specified. This suggests that if the crystal growth velocity V of the range of the silicon single crystal is within the upper limit value (VUL) and lower limit value (VLL) the quality of a section of this part is satisfactory. The range between the upper limit value (VUL) and the lower limit value (VLL) is referred to as the permissible range. A permissible range exists in each part of the silicon single crystal and is not necessarily constant across all parts. This is clear from the changes in the permissible range shown in FIG. 3. In addition, the permissible range alters according to the determined product standards. Based on this, the permissible range of all parts of the silicon single crystal or in each predetermined part must be determined, and it must be determined in accordance with the product standards.

FIG. 5 is a diagram showing the relationship between the GAP distance d and LPD number in an arbitrary part of the silicon single crystal. As shown in FIG. 5, a correlative relationship exists between the GAP distance d and LPD number. When the GAP distance d increases, the LPD increases and, conversely, when the GAP distance d decreases, the LPD decreases. This relationship suggests that if the GAP distance d is small, the LPD will be decreased. However, ID is generated in the outer circumferential part of the wafer when the GAP distance d drops below a predetermined distance.

Similarly to the crystal growth velocity V, the correlative relationship shown in FIG. 5 can be employed to specify the range of the GAP distance d corresponding to the product standards. A permissible range exists for each part of the silicon single crystal and is not necessarily constant across all parts. In addition, the permissible range alters according to the determined product standards. Based on this, the permissible range of all parts of the silicon single crystal or in each predetermined part must be determined, and it must be determined in accordance with the product standards.

V/G must be controlled within a certain permissible range to maintain uniform defect distribution in the crystal axis direction. FIG. 6 is a diagram that shows the relationship between the crystal growth velocity V and GAP distance d having the greatest effect in terms of controlling V/G. As is clear from FIG. 6, when the control accuracy of one of either the crystal growth velocity V or the GAP distance d is improved, the permissible range of the other expands. For example, by suppressing the GAP control width of FIG. 6 from X to X′, the permissible range of the crystal growth velocity V can be expanded from Y to Y′. Accordingly, if either one of the control parameters is rigidly controlled, the permissible range of the other control parameter can be expanded and the silicon single crystal satisfactory product rate can be improved without need for the rigid control of the other control parameter.

Next, the method for determining the permissible ranges will be explained. The line of thinking related to the permissible range is the same for the crystal growth velocity V and the GAP distance d. Accordingly, the method for determining the permissible range of the crystal growth velocity V alone will be explained.

In order to determine the permissible range of the crystal growth velocity V, a level test for the crystal growth velocity V was carried out using a GAP distance d set value. As shown by FIG. 7, in the level test, crystals are grown at growth conditions increased an arbitrary velocity width (pattern a) and decreased by an arbitrary velocity width (pattern c) with respect to an existing set crystal growth velocity V (pattern b). While these three levels are mentioned as an example, the number of levels may be determined as appropriate in accordance with need. Then, the defect behaviour and the defect distribution in the radial direction of the silicon single crystal were evaluated. At this time, two silicon single crystals pulled up at the crystal growth velocity V of the same level were prepared, one silicon single crystal of which was sliced into wafers and, following mirror finishing, was subjected to LPD evaluation, while the other silicon single crystal was cut into specimens in the pulling axis direction and, following the administering of thermal oxidation processing or Cu decoration processing on cut-out specimens, defect distribution was observed by X-ray topography (X-ray diffraction microscopy method) and the presence or absence of the generation of ID was confirmed.

FIGS. 8A through 8C are diagrams showing the inspection results in an A region of the pattern a shown in FIG. 7. FIG. 8A shows the axial direction distribution of the LPD number, FIG. 8B shows the defect distribution evaluated from a specimen cut vertically from the crystal, and FIG. 8C shows the relationship between the silicon single crystal length and the crystal growth velocity V.

FIGS. 9A through 9C are diagrams showing the inspection results in the A region of the pattern b shown in FIG. 7. FIG. 9 A shows the axial direction distribution of the LPD number, FIG. 9B shows the defect distribution evaluated from a specimen cut vertically from the crystal, and FIG. 9C shows the relationship between the silicon single crystal length and the crystal growth velocity V.

FIGS. 10A through 10C are diagrams showing the inspection results in the A region of the pattern c shown in FIG. 7. FIG. 10A shows the axial direction distribution of the LPD number, FIG. 10B shows the defect distribution evaluated from a specimens cut vertically from the crystal, and FIG. 10C shows the relationship between the silicon single crystal length and the crystal growth velocity V.

It is confirmed from FIGS. 8A and B that while there is no ID present in the a region, that is to say, in all regions, the LPD standard is not met. Accordingly, the entire region is judged to be a NG region.

It is confirmed from FIGS. 9A and B that while the LPD standard is met and there is an absence of ID defects in the b2 region, the LPD in the b1 region is outside the standard. In this case, the b2 region in which the LPD standard and the ID standard are met is judged as an OK region, and the b 1 region in which the LPD standards is not met is judged as an NG region.

It is confirmed from FIGS. 10A and B that while the LPD standard is met and there is an absence of ID defects in the c2 region, the LPD standard is not met in the c1 region and ID defects are present in the c3 region. In this case, the c2 region in which the LPD standard and the ID standard are met is judged as an OK region, the c1 region in which the LPD standard is not met is judged as an NG region, and the c3 region in which the ID standard is not met is judged as an NG region.

By conducting the level test and the inspections of the defect distribution described above while altering the set range, the range of the crystal growth velocity V can be determined so that the LPD standard is met and ID are eliminated in each part (crystal position) of the silicon single crystal as shown in FIG. 11. This range is taken as the permissible range of the crystal growth velocity V.

While the method for determining the permissible range of the crystal growth velocity V has been explained, in order to determine the permissible range of the GAP distance d, a level test for the GAP distance d should be carried out using a fixed crystal growth velocity V.

Moreover, while in this embodiment the LPD standard and the absence of ID defects are adopted as quality guarantee standards, and the permissible range of the crystal growth velocity V and GAP distance d are set with the actual value thereof being determined by employing the log data and the actual value and permissible range being compared, the permissible range of control parameters of other CZ single crystal processes can be set for the other quality elements (for example, Ar flow rate, furnace pressure, GAP distance, crystal rotation velocity, crucible rotation velocity, magnetic field intensity and heater temperature and so on) and can have application in similar judgment processing.

According to this embodiment, the log data of control parameters during crystal growth is employed to evaluate the quality of all regions of the silicon single crystal. The evaluation of all regions of the silicon single crystal suggests that the accuracy of this quality inspection is comparatively higher than conventional sampling inspection in which a part of the silicon single crystal is extracted and evaluated. In addition, the satisfactory product region and the unsatisfactory product region of the single-crystal silicon can be reliably ascertained. Accordingly, the wafer finishing processing on unsatisfactory wafers is eliminated and operational efficiency is improved. In addition, the discarding of satisfactory wafers is eliminated and yield is improved.

### BRIEF DESCRIPTION OF THE DRAWINGS

FIG. 1 is a diagram showing the configuration of a CZ method single crystal pulling apparatus used in this embodiment.

FIG. 2 is a flow chart showing the steps for manufacturing of a silicon wafer including the present invention.

FIG. 3 is a diagram showing one example of the corresponding relationship between the actual value of the crystal growth velocity, the permissible range of the crystal growth velocity, and the silicon single crystal part.

FIG. 4 is a diagram showing the relationship between the crystal growth velocity V and LPD number in an arbitrary part of the silicon single crystal.

FIG. 5 is a diagram showing the relationship between the GAP distance d and LPD number in an arbitrary part of the silicon single crystal.

FIG. 6 is a diagram showing the relationship between the crystal growth velocity V and GAP distance d.

FIG. 7 is a diagram showing an example of crystal growth velocity V setting of several experiments.

FIGS. 8A through 8C are diagrams showing the inspection results in the A region of the pattern a shown in FIG. 7, in which FIG. 8A is a diagram showing the axial direction distribution of the LPD number, FIG. 8B is a diagram showing the defect distribution evaluated from a vertically cut specimen from the crystal, and FIG. 8C is a diagram showing the relationship between the silicon single crystal length and crystal growth velocity V.

FIGS. 9A through 9C are diagrams showing the inspection results in the A region of the pattern b shown in FIG. 7, in which FIG. 9A is a diagram showing the axial direction distribution of the LPD number, FIG. 9B is a diagram showing the defect distribution evaluated from a vertically cut specimen from the crystal, and FIG. 9C is a diagram showing the relationship between the silicon single crystal length and crystal growth velocity V.

FIGS. 10A through 10(d) are diagrams showing the inspection results in the A region of the pattern c shown in FIG. 7, in which FIG. 10A is a diagram showing the axial direction distribution of LPD number, FIG. 10B is a diagram showing the defect distribution evaluated from a vertically cut specimen from the crystal, and FIG. 10C is a diagram showing the relationship between the silicon single crystal length and crystal growth velocity V.

FIG. 11 is a diagram showing a method for determining the permissible width of the crystal growth velocity V based on the level test.

FIG. 12 is a flow chart showing the steps for the manufacturing of a silicon wafer.

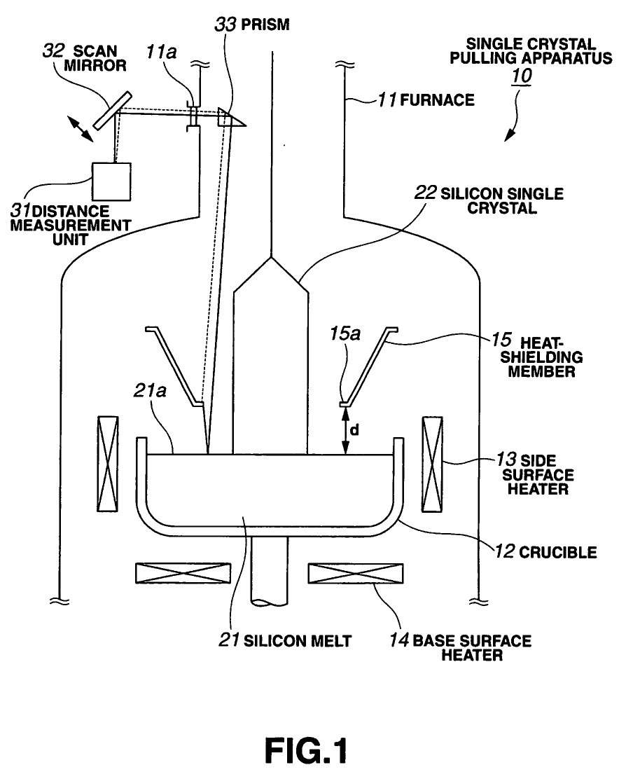

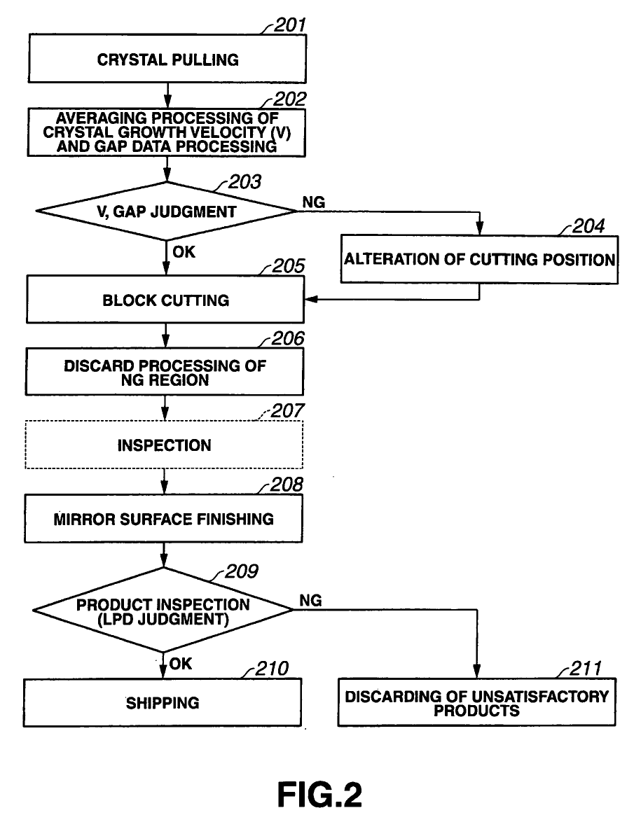

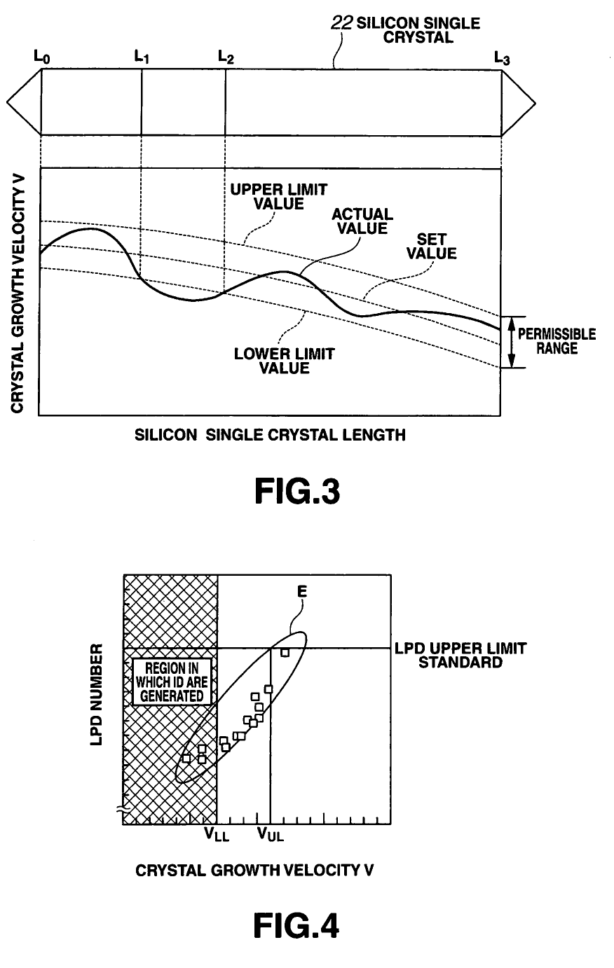

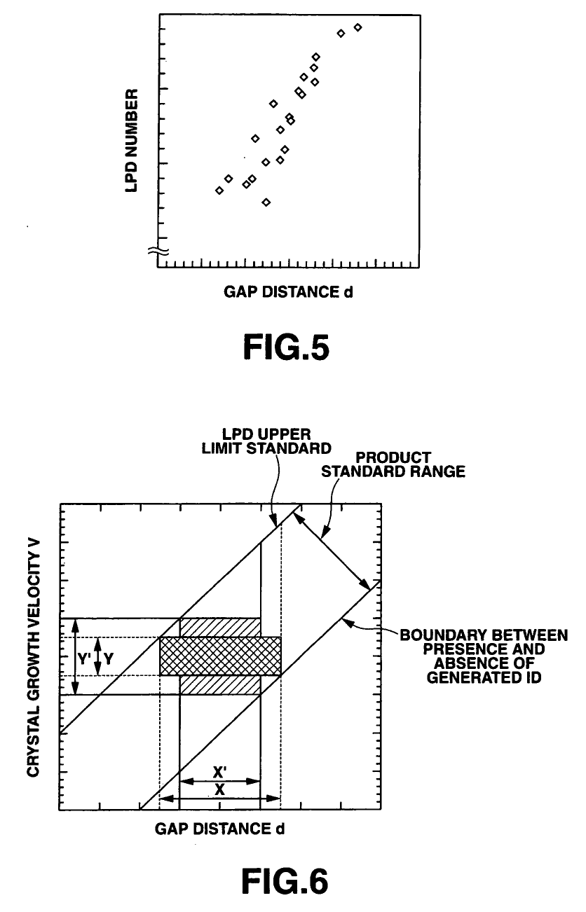

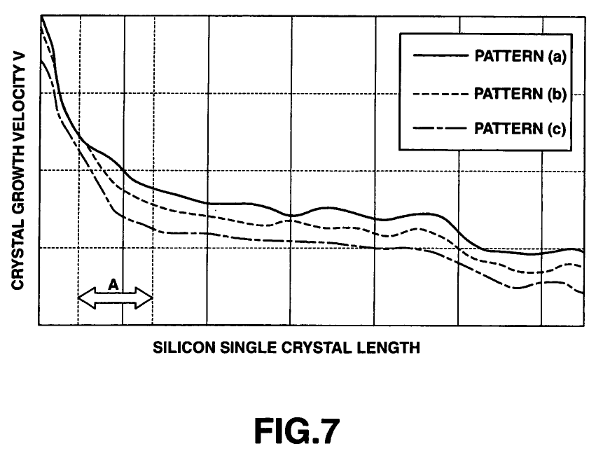

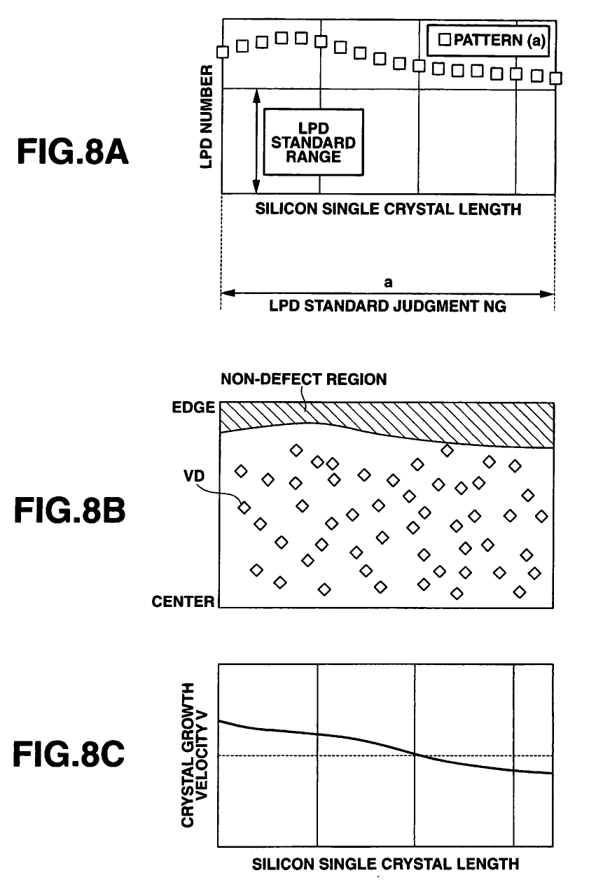

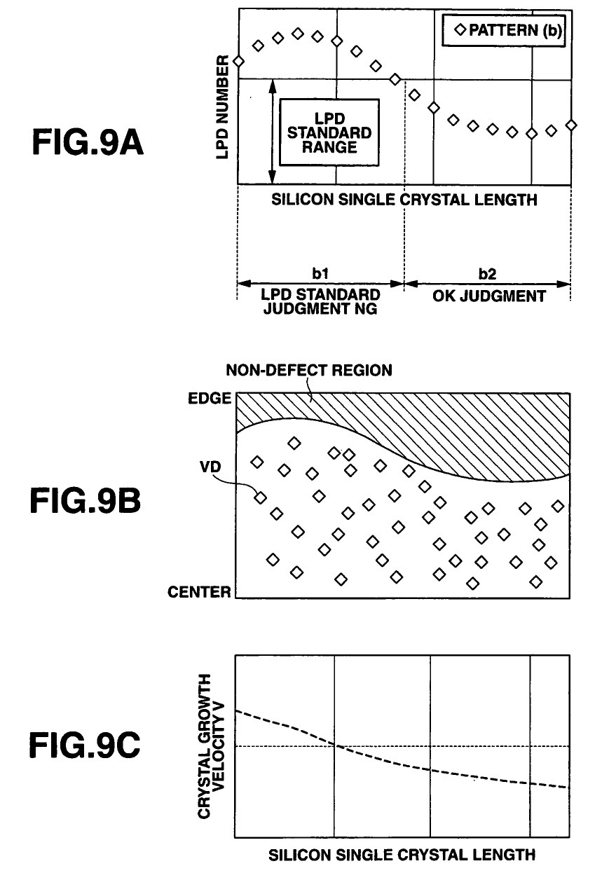

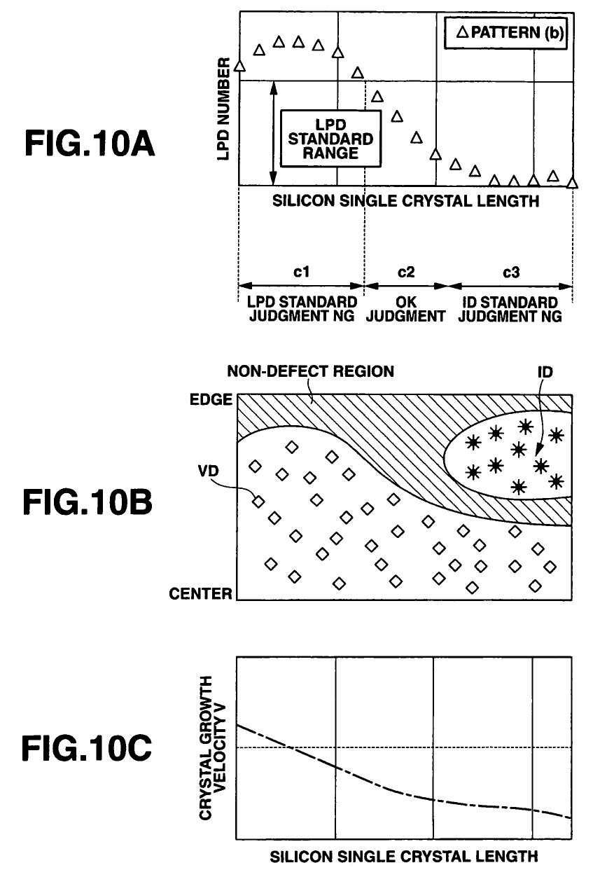

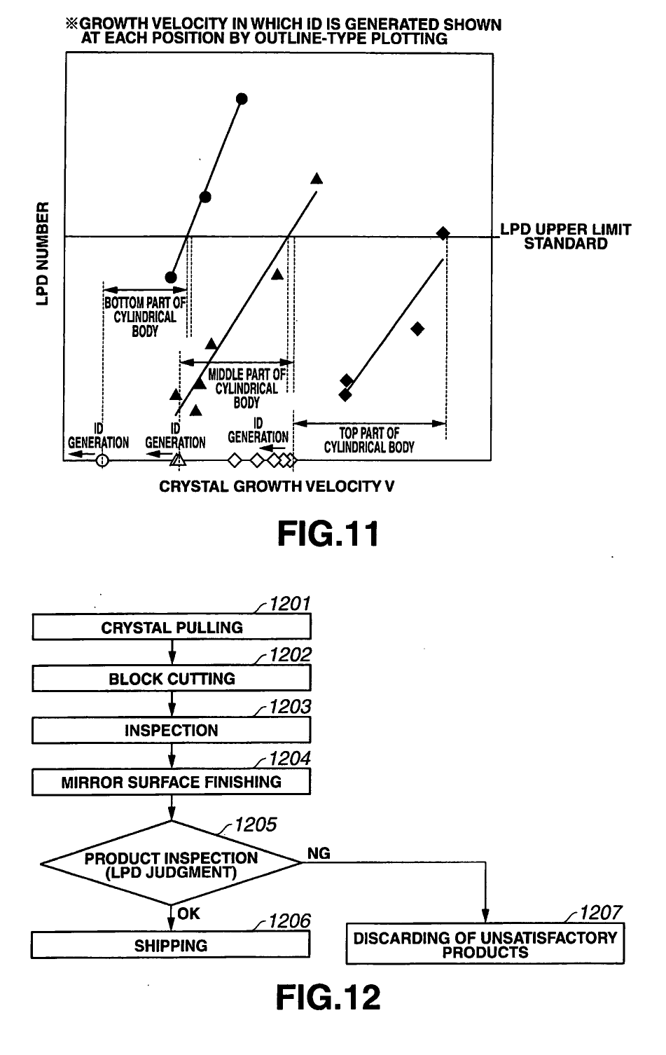

### EXPLANATION OF REFERENCE SYMBOLS

10 single crystal pulling apparatus
12 crucible
15 heat shielding member
21 silicon melt
22 silicon single crystal

1. A method of evaluating quality of a silicon single crystal in which the quality of the silicon single crystal pulled up from a silicon melt is evaluated, comprising:
measuring a control parameter that has an effect on the quality of the silicon single crystal during pulling up of the silicon single crystal; and
determining a quality satisfactory part and a quality unsatisfactory part of the silicon single crystal by employing a predetermined permissible range of a control parameter and the measured control parameter.

2. A method of evaluating quality of a silicon single crystal in which the quality of the silicon single crystal pulled up from a silicon melt is evaluated, comprising:
a process for measuring a control parameter having an effect on the quality of the silicon single crystal during pulling up of the silicon single crystal;
a process for determining a correlative relationship between a silicon single crystal part and the control parameter by employing the measured control parameter; and
a process for comparing a permissible range of a control parameter set in advance and the control parameter in the correlative relationship to judge the silicon single crystal part corresponding to the control parameter in the permissible range as a quality satisfactory part, and the silicon single crystal part corresponding to the control parameter outside the permissible range as a quality unsatisfactory product part.

3. The method of evaluating quality of a siliconⁱ single crystal according to claim 1 or claim 2, wherein the control parameter is the crystal growth velocity of the silicon single crystal.

4. The method of evaluating quality of a single crystal according to claim 1 or claim 2, wherein the control parameter is a distance from a lower edge of a heat-shielding plate arranged above a silicon melt for shielding the silicon single crystal from radiant heat to a surface of the silicon melt.
